(19) United States
(12) Patent Application Publication
(10) Pub. No.: US 2013/0120911 A1
(43) Pub. Date: May 16, 2013

(54) HANDHELD ELECTRONIC DEVICE WITH A PRESSURE-SENSITIVE ADHESIVE SHEET

(71) Applicant: Charles CHOU, Taipei (TW)

(72) Inventor: Charles CHOU, Taipei (TW)

(21) Appl. No.: 13/293,621

(22) Filed: Nov. 10, 2011

(51) Int. Cl. H05K 5/00

(52) U.S. Cl. 361/679.01

(57) ABSTRACT

A handheld electronic device has a device body and a pressure-sensitive adhesive sheet. The device body includes a smooth surface. The pressure-sensitive adhesive sheet includes a film and a membrane. The film has an external surface and an internal surface. The external surface is uncolored or single-colored for a user to draw a desired picture. The membrane is made of a pressure-sensitive adhesive and silicon dioxide and is attached to the internal surface of the film. The pressure-sensitive adhesive sheet is pressed to the device body so as to make the membrane firmly adhered to the smooth surface of the device body. Therefore, the handheld electronic device can be customizable. Besides, the pressure-sensitive adhesive sheet can be easily peeled off, which causes no damage to the pressure-sensitive adhesive sheet and the device body so that the user can easily change the appearance of the handheld electronic device for variety.

### BACKGROUND OF THE INVENTION

1. Field of the Invention

The present invention relates to a handheld electronic device, and more particularly to a handheld electronic device with a pressure-sensitive adhesive sheet for a user to draw a picture and thereby to alter the appearance of the handheld electronic device.

2. Description of the Prior Arts

Handheld electronic devices, such as smart phones, tablet personal computers (tablet PCs), personal digital assistants (PDAs), have become increasingly popular because of their portability and multiple functions they can perform.

Handheld electronic devices are standard and common in appearance, but users desire a unique appearance to satisfy their personal tastes and preferences. Therefore, a sticker with a design is used to stick to the handheld electronic device to alter the appearance of the handheld electronic device.

However, the sticker creates problems when users attempt to peel off and replace the sticker with various stickers of different designs. Peeling off the sticker will result in some damage to the sticker and the adhesive of the sticker will leave a residue on the handheld electronic device.

To overcome the shortcomings, the present invention provides a handheld electronic device with a pressure-sensitive adhesive sheet to mitigate or obviate the aforementioned problems.

### SUMMARY OF THE INVENTION

The main object of the present invention is to provide a handheld electronic device with a pressure-sensitive adhesive sheet for a user to draw a picture and thereby to alter the appearance of the handheld electronic device.

To achieve the foregoing objective, the handheld electronic device in accordance with the present invention comprises a device body and a pressure-sensitive adhesive sheet. The device body includes a smooth surface. The pressure-sensitive adhesive sheet includes a film and a membrane. The film has an external surface and an internal surface. The external surface is uncolored or single-colored for a user to draw a desired picture. The membrane is made of a pressure-sensitive adhesive and silicon dioxide and has an external surface and an internal surface. The external surface is attached to the internal surface of the film. The pressure-sensitive adhesive sheet is pressed to the device body so as to make the internal surface of the membrane firmly adhered to the smooth surface of the device body. Therefore, the handheld electronic device can be customizable to represent the tastes and preferences of the user. Besides, the pressure-sensitive adhesive sheet can be easily peeled off, which causes no damage to the pressure-sensitive adhesive sheet and the device body so that the user can easily change the appearance of the handheld electronic device for variety.

Other objectives, advantages and novel features of the invention will become more apparent from the following detailed description when taken in conjunction with the accompanying drawings.

### BRIEF DESCRIPTION OF THE DRAWINGS

FIG. 1 is an exploded perspective view of a handheld electronic device in accordance with the present invention;

FIG. 2 is a perspective view of the handheld electronic device in FIG. 1;

FIG. 3 is a perspective view of another embodiment of a protective case of the handheld electronic device in accordance with the present invention; and

FIG. 4 is a perspective view of a handheld electronic device with the protective case in FIG. 3.

### DETAILED DESCRIPTION OF THE PREFERRED EMBODIMENTS

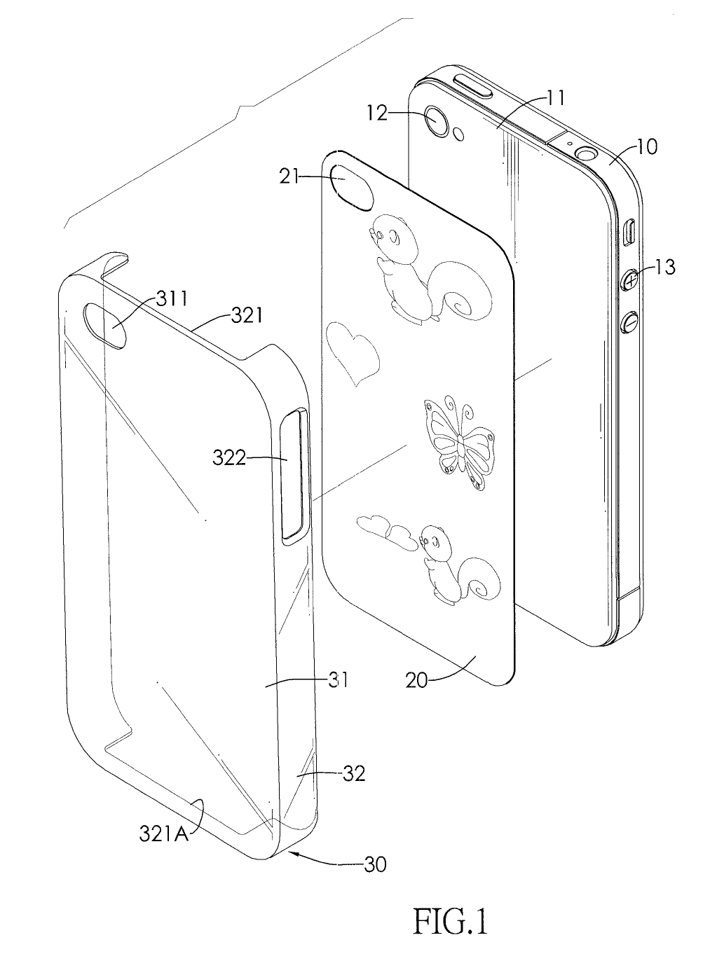

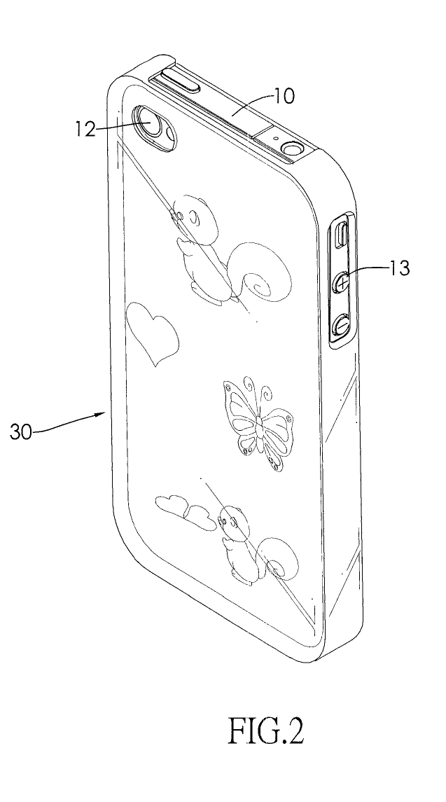

With reference to FIGS. 1 and 2, a handheld electronic device in accordance with the present invention comprises a device body 10, a pressure-sensitive adhesive (PSA) sheet 20 and a protective case 30.

The device body 10 includes a smooth surface 11, a camera lens 12 and multiple control units 13 and may be a smart phone, a tablet personal computer (tablet PC), a personal digital assistant (PDA), etc.

The pressure-sensitive adhesive sheet 20 includes a film, a membrane and a hole 21. The film has an external surface and an internal surface. The external surface is uncolored or single-colored for a user to draw a desired picture. The film may be made of polycarbonate (PC) or polythylene terephthalate (PET) so that the user can use a permanent marker to draw on the film. The film may be made of paper so that the user can use both a permanent marker and a water-based pen to draw on the film. The membrane is made of a pressure-sensitive adhesive and silicon dioxide and has an external surface and an internal surface. The external surface is attached to the internal surface of the film. The pressure-sensitive adhesive sheet 20 is pressed to the device body 10 so as to make the internal surface of the membrane firmly adhered to the smooth surface 11 of the device body 10. The pressure-sensitive adhesive may be a polyacrylate adhesive, a polyvinyl alcohol adhesive, a polyvinyl acetate adhesive or a synthetic rubber adhesive. The hole 21 corresponds to the camera lens 12 of the device body 10.

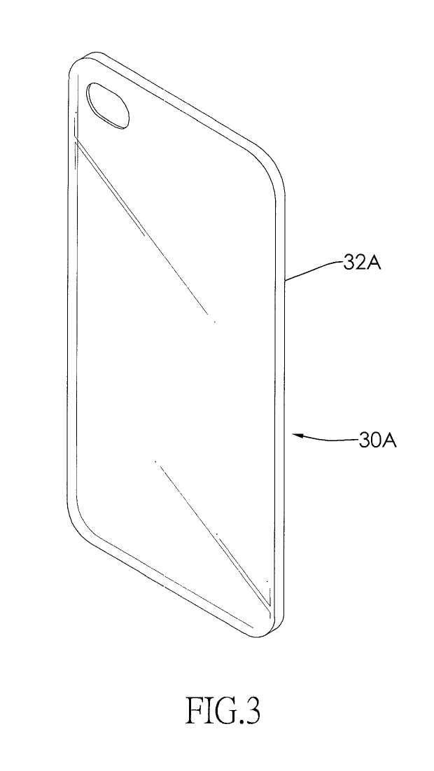

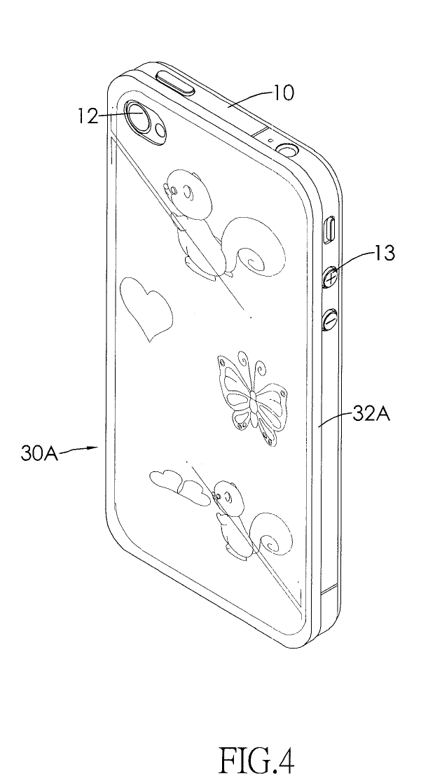

The protective case 30 covers the pressure-sensitive adhesive sheet 20 and detachably holds the device body 10 in order to protect the pressure-sensitive adhesive sheet 20 and the device body 10. The protective case 30 is transparent so that the picture on the pressure-sensitive adhesive sheet 20 can be showed clearly. The protective case 30 includes a backing 31 and an annular sidewall 32. The backing 31 is attached to the pressure-sensitive adhesive sheet 20 and has a first aperture 311 corresponding to the hole 21 of the pressure-sensitive adhesive sheet 20. The annular sidewall 32 is wrapped around the device body 10 and has a trop notch 321, a bottom notch 321A and a second aperture 322. The top and bottom notches 321, 321A allow the user to conveniently detach the protective case 30 from the device body 10. The second aperture 322 allows the control units 13 of the device body 10 to be disposed inside thereof and is conveniently provided for operation of the control units 13. With reference to FIGS. 3 and 4, in another embodiment, the annular sidewall 32A of the protective case 30A is shorter in width for convenient assembly and no notch or aperture formed on the annular sidewall 32A is required.

The handheld electronic device comprising the pressure-sensitive adhesive sheet 20 allows the user to draw a desired picture to obtain a unique appearance of the handheld electronic device. Therefore, the handheld electronic device can be customizable to represent the tastes and preferences of the user. Besides, the pressure-sensitive adhesive sheet 20 can be easily peeled off, which causes no damage to the pressure-sensitive adhesive sheet 20 and the device body 10 so that the user can easily change the appearance of the handheld electronic device for variety.

Even though numerous characteristics and advantages of the present invention have been set forth in the foregoing description, together with details of the structure and features of the invention, the disclosure is illustrative only. Changes may be made in the details, especially in matters of shape, size and arrangement of parts within the principles of the invention to the full extent indicated by the broad general meaning of the terms in which the appended claims are expressed.

What is claimed is:

1. A handheld electronic device comprising:
a device body including a smooth surface; and
a pressure-sensitive adhesive sheet including
a film having
an external surface being single-colored; and
an internal surface; and
a membrane made of a pressure-sensitive adhesive and silicon dioxide and having
an external surface attached to the internal surface of the film; and
an internal surface adhered to the smooth surface of the device body.

2. The handheld electronic device as claimed in claim 1 further comprising a protective case being transparent, covering the pressure-sensitive adhesive sheet and detachably holding the device body.

3. The handheld electronic device as claimed in claim 1, wherein
the device body includes a camera lens; and
the pressure-sensitive adhesive sheet includes a hole corresponding to the camera lens of the device body.

4. The handheld electronic device as claimed in claim 2, wherein
the device body includes a camera lens;
the pressure-sensitive adhesive sheet includes a hole corresponding to the camera lens of the device body; and
the protective case includes a first aperture corresponding to the hole of the pressure-sensitive adhesive sheet.

5. The handheld electronic device as claimed in claim 2, wherein the protective case includes a top notch and a bottom notch.

6. The handheld electronic device as claimed in claim 4, wherein the protective case includes a top notch and a bottom notch.

7. The handheld electronic device as claimed in claim 5, wherein
the device body includes multiple control units; and
the protective case includes a second aperture in which the control units of the device body are disposed.

8. The handheld electronic device as claimed in claim 6, wherein
the device body includes multiple control units; and
the protective case includes a second aperture in which the control units of the device body are disposed.

9. The handheld electronic device as claimed in claim 8, wherein the protective case includes
a backing attached to the pressure-sensitive adhesive sheet and having the first aperture; and
an annular sidewall wrapped around the device body and having the top notch, the bottom notch and the second aperture.

10. The handheld electronic device as claimed in claim 9, wherein the pressure-sensitive adhesive is a polyacrylate adhesive.

11. The handheld electronic device as claimed in claim 9, wherein the pressure-sensitive adhesive is a polyvinyl alcohol adhesive.

12. The handheld electronic device as claimed in claim 9, wherein the pressure-sensitive adhesive is a polyvinyl acetate adhesive.

13. The handheld electronic device as claimed in claim 9, wherein the pressure-sensitive adhesive is a synthetic rubber adhesive.

14. The handheld electronic device as claimed in claim 9, wherein the film is made of polycarbonate.

15. The handheld electronic device as claimed in claim 9, wherein the film is made of polythylene terephthalate.

16. The handheld electronic device as claimed in claim 9, wherein the film is made of paper.
